(19) United States
(12) Patent Application Publication
(10) Pub. No.: US 2014/0175480 A1
(43) Pub. Date: Jun. 26, 2014

(54) LED DIE AND METHOD FOR MANUFACTURING LED INCORPORATING THE SAME

(71) Applicant: HON HAI PRECISION INDUSTRY CO., LTD., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 13/936,294

(22) Filed: Jul. 8, 2013

(30) Foreign Application Priority Data
Dec. 21, 2012 (TW) 101148936

(51) Int. Cl. H01L 33/50

(52) U.S. Cl. CPC H01L 33/50
USPC 257/98; 438/27

(57) ABSTRACT

An LED die includes a substrate, a first semiconductor layer, a light emitting layer, a second semiconductor layer, a first electrode and a second electrode. A phosphor layer is formed on the second semiconductor layer. The phosphor layer has a constant thickness at a main light emitting face of the second semiconductor layer. A method for manufacturing an LED incorporating the die is also disclosed.

### BACKGROUND

1. Technical Field

The disclosure generally relates to an LED (light emitting diode) die, and more particularly, to an LED die having uniformly distributed phosphor.

2. Description of Related Art

Nowadays LEDs (light emitting diodes) are applied widely in various applications for illumination. A typical LED includes a chip, an encapsulant sealing the chip and phosphor doped within the encapsulant. The phosphor can change the blue light emitted from the chip to yellow light, which mixes with the blue light to obtain white light. However, during manufacturing processes of the LED, the phosphor is prone to be locally accumulated within the encapsulant, thereby resulting in uneven distribution of the phosphor. Such uneven distribution of the phosphor will affect uniform mixing of the yellow light with the blue light. As a result, color aberration of the white light may occur.

What is needed, therefore, is an LED chip and a method for manufacturing an LED incorporating the chip which can address the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the various views.

FIG. 1 shows a first step of a process of manufacturing an LED in accordance with an embodiment of the present disclosure.

FIG. 2 shows a second step of manufacturing the LED in accordance with the embodiment of the present disclosure.

FIG. 3 shows a third step of manufacturing the LED in accordance with the embodiment of the present disclosure.

FIG. 4 shows a fourth step of manufacturing the LED in accordance with the embodiment of the present disclosure.

FIG. 5 shows a fifth step of manufacturing the LED in accordance with the embodiment of the present disclosure.

FIG. 6 shows a sixth step of manufacturing the LED in accordance with the embodiment of the present disclosure.

FIG. 7 shows a seventh step of manufacturing the LED in accordance with the embodiment of the present disclosure.

FIG. 8 shows the LED which has been manufactured after the steps of the process of FIGS. 1-7.

### DETAILED DESCRIPTION

A method for manufacturing an LED in accordance with an embodiment of the present disclosure is disclosed. The method mainly includes several steps discussed below.

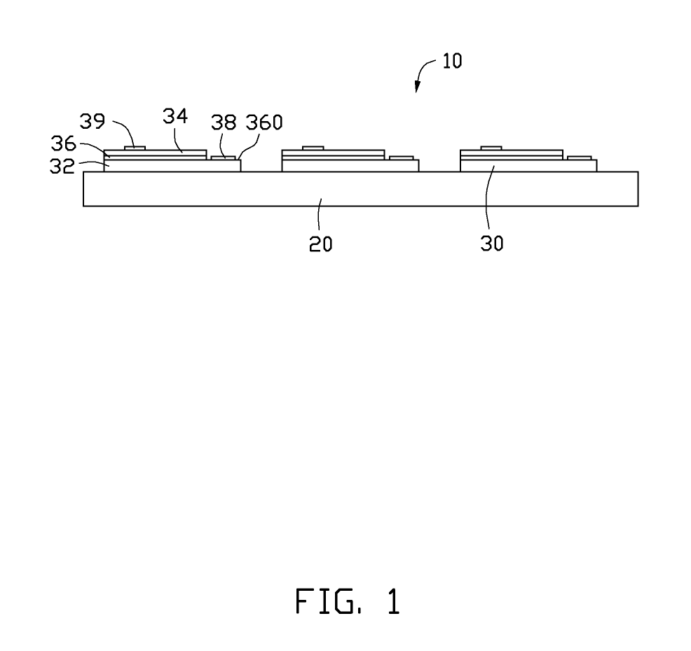

Firstly, as shown in FIG. 1, a wafer 10 is provided. The wafer 10 includes a substrate 20 and a plurality of chips 30 formed on the substrate 20. The substrate 20 may be made of Al₂O₃, Si, SiC or other suitable materials. Each chip 30 includes a first semiconductor layer 32, a light emitting layer 36 and a second semiconductor layer 34. In this embodiment, the first semiconductor layer 32 is an N-type semiconductor layer, the second semiconductor layer 34 is a P-type semiconductor layer, and the light emitting layer 36 is a multiple quantum well layer. The light emitting layer 36 can emit blue light when activated. The second semiconductor layer 34 and the light emitting layer 36 have areas less than that of the first semiconductor layer 32. A part of a top face of the first semiconductor layer 32 uncovered by the light emitting layer 36 forms a platform 360. A first electrode 38 is formed on the platform 360, and a second electrode 39 is formed on a top face of the second semiconductor layer 34. The first electrode 38 is lower than the second electrode 39. The first electrode 38 and the second electrode 39 are both made of metallic material such as Au, Ni or an alloy thereof.

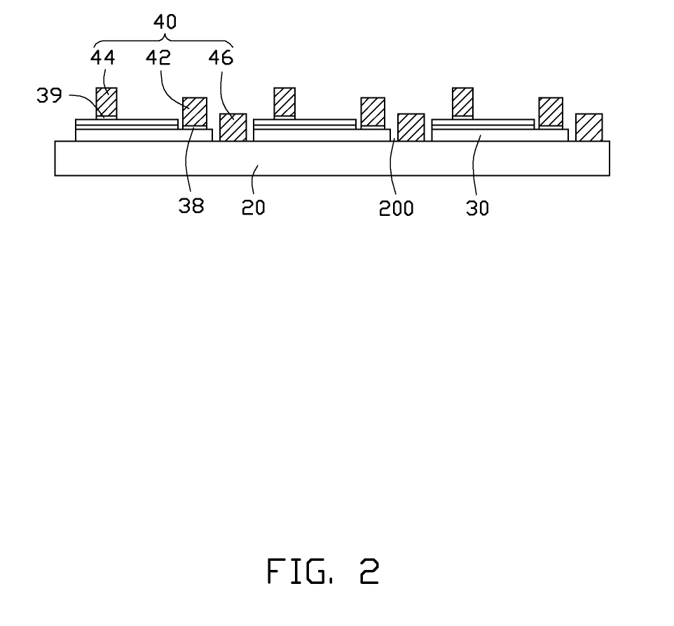

A photoresist layer 40 is then formed on the wafer 10 as shown in FIG. 2. The photoresist layer 40 includes a first block 42 formed on the first electrode 38, a second block 44 formed on the second electrode 39 and a third block 46 formed on a top face of the substrate 20. The first block 42, the second block 44 and the third block 46 are separated and spaced from each other. Each of the first block 42, the second block 44 and the third block 46 has a constant height from a bottom to a top thereof. A top face of the first block 42 has an area larger than that of the second block 44, and less than that of the third block 46. Preferably, the area of the top face of the first block 42 is equal to an area of a top face of the first electrode 38, the area of the top face of the second block 44 is equal to an area of a top face of the second electrode 39, and the area of the top face of the third block 46 is less than an area of a top face of the substrate 20 between two adjacent chips 30. A gap 200 is defined between the third block 46 and an adjacent chip 30. Levels of the top faces of the second block 44, the first block 42 and the third block 46 gradually decrease along that sequence. In this embodiment, the top face of the third block 46 is located higher than the top face of the second electrode 39.

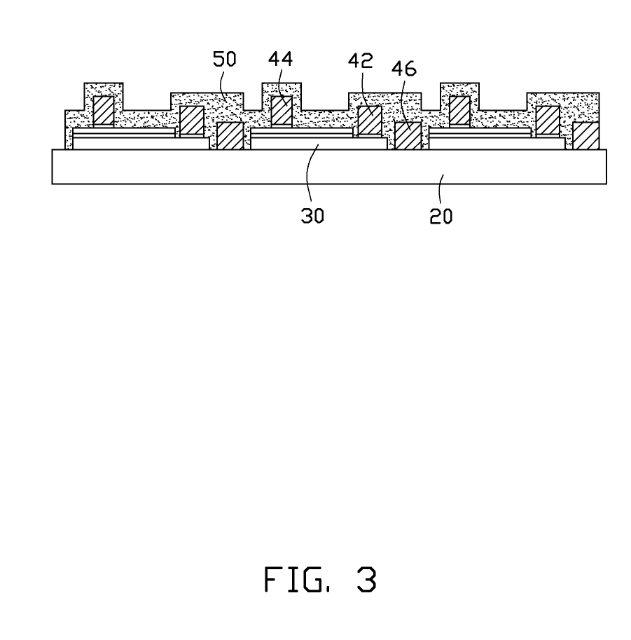

Also referring to FIG. 3, a continuous phosphor layer 50 is then formed on the wafer 10 and the photoresist layer 40. The phosphor layer 50 is uniformly distributed on the wafer 10 and the photoresist layer 40 by rotately spreading phosphor material on the wafer 10 and the photoresist layer 40. The phosphor layer 50 completely covers the photoresist layer 40 and the chips 30. The phosphor layer 50 has an uneven top face which has a plurality of protrusions and grooves alternately formed thereon. The phosphor layer 50 may be made of silicate, yttrium aluminum garnet or other suitable materials. The phosphor layer 50 can change the blue light emitted from each chip 30 to yellow light, thereby obtaining mixed white light.

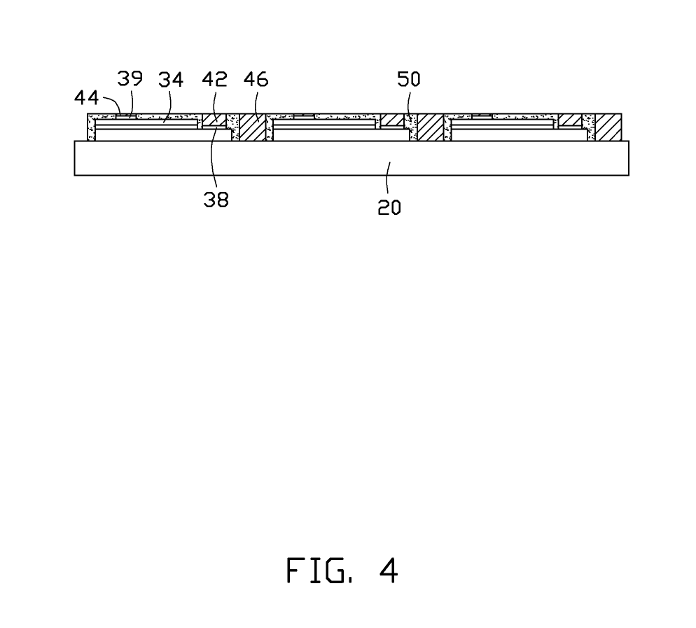

The phosphor layer 50 is then flattened as shown in FIG. 4. Preferably, the phosphor layer 50 is flattened by chemically-mechanically processing (such as chemical milling). The flattened phosphor layer 50 has a constant thickness at the second semiconductor layer 34 of each chip 30. Thus, the phosphor layer 50 is uniformly distributed on a main light emitting face (i.e., the top face of the second semiconductor layer 34) of each chip 30, thereby preventing color aberration of the mixed white light. The photoresist layer 50 is also partially removed accompanying the polishing of the phosphor layer 50. The removed ratio of the photoresist layer 50 depends on the polishing degree. In this embodiment, most of the second block 44 is removed with only a very small part of the second block 44 remaining on the second electrode 39; a large part of the first block 42 is removed with a small part of the first block 42 remaining on the first electrode 38; a small part of the third block 46 is removed with a large part of the third block 46 remaining on the substrate 20. After polishing, the photoresist layer 40 and the phosphor layer 50 have coplanar top faces.

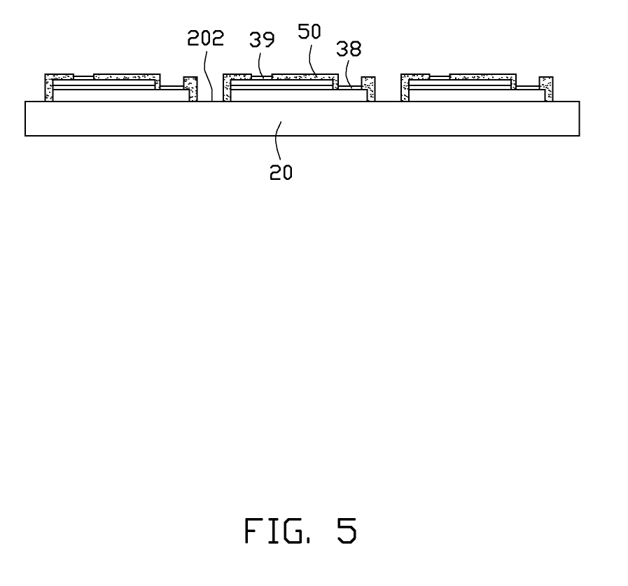

Also referring to FIG. 5, the photoresist layer 40 is completely removed by etching. The top face of the second electrode 39, the top face of the first electrode 38, and a part 202 of the top face of the substrate 20 between two adjacent chips 30 are exposed again. The phosphor layer 50 covers a top face of the second semiconductor layer 34 beside the second electrode 39, a top face of the platform 360 beside the first electrode 38, lateral faces of the first semiconductor layer 32, the second semiconductor layer 34 and the light emitting layer 36. The first electrode 38 and the second electrode 39 are exposed from the phosphor layer 50. The first electrode 38 and the second electrode 39 each have a thickness less than that of the phosphor layer 50.

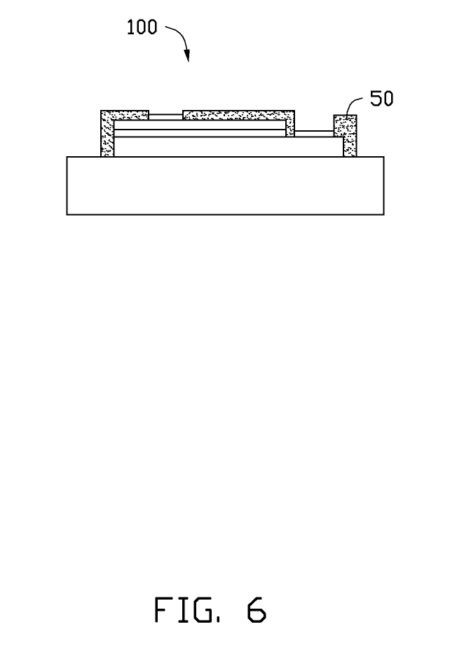

Also referring to FIG. 6, the substrate 20 is separated into a plurality of pieces by cutting through the substrate 20 at positions corresponding to the parts 202, respectively, thereby obtaining a plurality of individual dies 100.

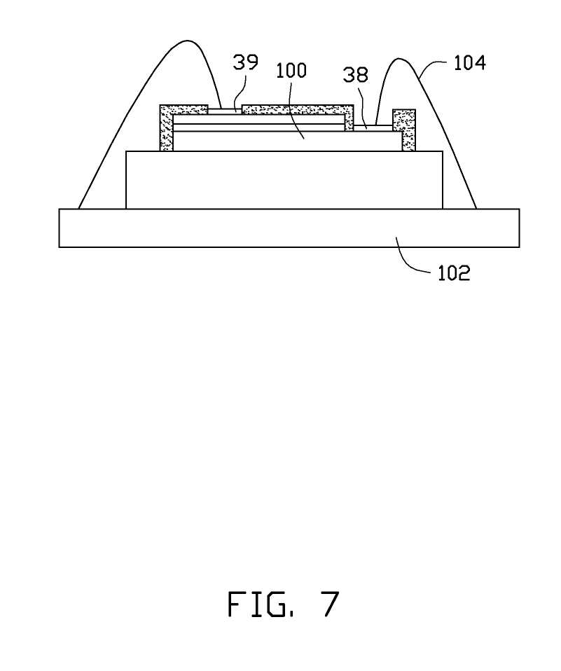

Each die 100 is then mounted on a base 102 and electrically connected to the base 102 as shown in FIG. 7. The first electrode 38 and the second electrode 39 are both electrically connected to the base 102 via metallic wires 104.

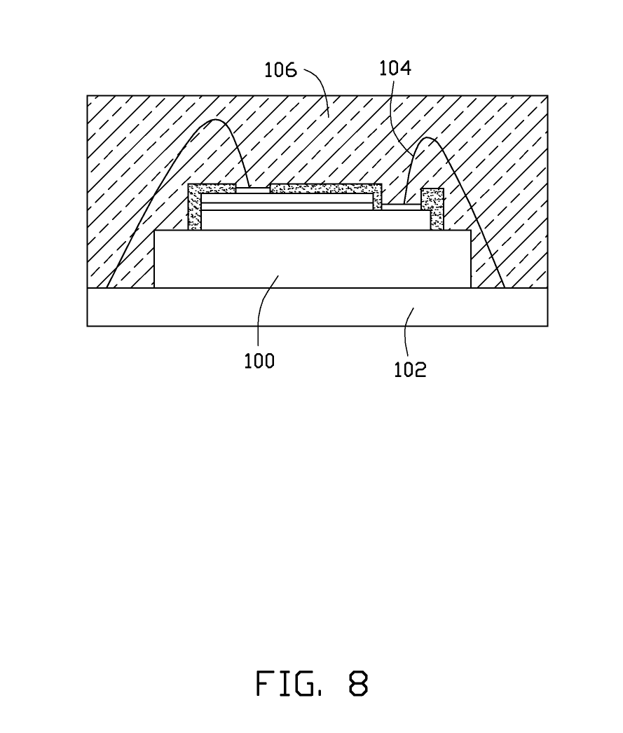

Finally, as shown in FIG. 8, an encapsulant 106 is formed on the base 102 to seal the chip 100 and the wire 104 therein. The encapsulant 106 may be made of silicone, epoxy or other transparent materials. In this embodiment, the encapsulant 106 does not contain any phosphor therein.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An LED (light emitting diode) die comprising:
a substrate;
a first semiconductor layer formed on the substrate;
a light emitting layer formed on the first semiconductor layer;
a second semiconductor layer formed on the light emitting layer, the second semiconductor layer comprising a main light emitting face; and
a phosphor layer covering the second semiconductor layer, the phosphor layer having a constant thickness on the main light emitting face of the second semiconductor layer.

2. The LED die of claim 1, wherein the phosphor layer extends from the main light emitting face of the second semiconductor layer to a face of the substrate supporting the first semiconductor layer.

3. The LED die of claim 1, wherein the phosphor layer further covers and directly connects lateral faces of the first semiconductor layer, the light emitting layer and the second semiconductor layer.

4. The LED die of claim 1, wherein the first semiconductor layer forms a platform besides the light emitting layer, the phosphor layer further covering a top face of the platform.

5. The LED die of claim 4 further comprising a first electrode formed on the top face of the platform and a second electrode formed on the main light emitting face of the second semiconductor layer, wherein the first electrode and the second electrode are directly connected to and exposed from the phosphor layer.

6. The LED die of claim 5, wherein the first electrode and the second electrode each have a thickness less than that of the phosphor layer.

7. A method for manufacturing an LED, comprising:
providing a wafer comprising a substrate and a plurality of chips formed on the substrate, each chip comprising a first semiconductor layer, a light emitting layer and a second semiconductor layer, the second semiconductor layer having a main light emitting face;
spreading a continuous phosphor layer on the wafer;
flattening the phosphor layer to make the phosphor layer having a constant thickness on the main light emitting layer of the second semiconductor layer;
cutting the substrate to form a plurality of individual dies, each die comprising a corresponding chip and a part of the substrate on which the corresponding chip is mounted and a part of the phosphor layer on the main light emitting face of the second semiconductor layer of the corresponding chip;
electrically connecting each die with a base; and
encapsulating each die to form the LED.

8. The method of claim 7, wherein each chip further comprises a first electrode formed on the first semiconductor layer and a second electrode formed on the second semiconductor layer.

9. The method of claim 8 further comprising forming a photoresist layer on the wafer before spreading the continuous phosphor layer.

10. The method of claim 9, wherein the photoresist layer comprises a first block covering the first electrode and a second block covering the second electrode, the first block being separated and spaced from the second block.

11. The method of claim 10, wherein the photoresist layer further comprises a third block formed on the substrate between two adjacent chips.

12. The method of claim 11, wherein a top face of the second block is higher than a top face of the first block, and the top face of the first block is higher than a top face of the third block.

13. The method of claim 11, wherein the photoresist layer is partially removed by the step of flattening the phosphor layer.

14. The method of claim 13, wherein the first block, the second block and the third block are all partially remained on the wafer after the photoresist layer is partially removed.

15. The method of claim 13, wherein the photoresist layer is further completely removed after flattening the phosphor layer.

16. The method of claim 15, wherein the photoresist layer is completely removed by etching.

17. The method of claim 15, wherein the first electrode and the second electrode are exposed from the phosphor layer after the photoresist layer is completely removed.

18. The method of claim 7, wherein the phosphor layer is flattened by chemically-mechanically polishing.
